(19) United States
(12) Patent Application Publication
(10) Pub. No.: US 2019/0186012 A1
(43) Pub. Date: Jun. 20, 2019

(54) THIN-FILM OPTICAL DEVICE WITH VARYING LAYER COMPOSITION

(71) Applicant: Eastman Kodak Company, Rochester, NY (US)

(72) Inventor: Lee William Tutt, Webster, NY (US)

(21) Appl. No.: 15/846,561

(22) Filed: Dec. 19, 2017

(51) Int. Cl. C23C 16/455; C23C 16/40; C03C 17/245; G02B 5/28; G02B 6/132

(52) U.S. Cl. CPC C23C 16/45544; C23C 16/45555; C23C 16/45527; C23C 16/405; C23C 16/403; C03C 2218/152; G02B 5/289; G02B 6/132; C03C 2217/212; C03C 2217/214; C03C 17/2456

(57) ABSTRACT

A thin-film optical device is formed on a substrate by atomic layer deposition. A mixing system provides a homogeneous gaseous mixture having a controllable ratio of first and second reactive gaseous materials. The first and second reactive gaseous materials each react with a third reactive gaseous material but do not react with each other. The homogeneous gaseous mixture is provided to a first inlet port, the third reactive gaseous material is provided to a second inlet port, and an inert gaseous material is provided to a third inlet port. The gas flows are directed through corresponding output channels of the delivery head toward the substrate. The mixing system is controlled to change the ratio of the first and second reactive gaseous materials as a function of time as the substrate is moved relative to the delivery head with an oscillating motion such that deposited layers have a varying composition.

### FIELD OF THE INVENTION

This invention pertains to the field of optical filters and more particularly to optical reflection filters fabricated using an atomic layer deposition process.

### BACKGROUND OF THE INVENTION

Rugate filters, also known as gradient index reflection filters, are a type of optical reflection filter. Rugate filters differ from discrete stacked filters in that the index of refraction varies as a function of the height with the deposited film. Typically, the optical thickness of the refractive index period determines the reflection band position, and the amplitude of the variation of the index of refraction determines the reflection bandwidth. As generally known, multiple reflection bands can be generated by serially depositing individual index of refraction profiles for each reflection band or, alternatively, by superimposing multiple index of refraction profiles and depositing the bands in parallel. The use of superposition allows for increased film complexity without adding to the mechanical thickness of the deposited film. In instances where superimposed indices exceed the material indices or result in excessively high slew rates of the material sources, both serial and parallel techniques can be used.

The technique to apply the film is typically by co-sputtering of multiple materials and changing the ratio of the deposited materials. This technique is relatively fast but involves the use of a vacuum chamber and produces a large amount of waste to due to the need to position the sample at a sufficient distance to achieve relatively good uniformity. Rotation of the sample to achieve uniformity, which is effective, means that the deposition must be slow enough that the changes in the ratio of deposited material are still applied uniformly during the rotations.

A technique which yields extremely precise layer thicknesses and uniformity is atomic layer deposition (ALD). Atomic layer deposition (“ALD”) is a film deposition technology that can provide improved thickness resolution and conformal capabilities, compared to sputtering of the materials. The ALD process segments the conventional thin-film deposition process into single atomic-layer deposition steps. Advantageously, ALD steps are self-terminating and can deposit one atomic layer when conducted up to or beyond self-termination exposure times. An atomic layer typically ranges from about 0.1 to about 0.5 molecular monolayers, with typical dimensions on the order of no more than a few Angstroms. In ALD, deposition of an atomic layer is the outcome of a physical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the absence of the other precursor or precursors of the reaction. In practice, in any system it is difficult to avoid some direct reaction of the different precursors leading to a small amount of chemical vapor deposition reaction. The goal of any system claiming to perform ALD is to obtain device performance and attributes commensurate with an ALD system.

In ALD applications, typically two molecular precursors are introduced into the ALD reactor in separate stages. For example, a metal precursor molecule, MLₓ, comprises a metal element, M that is bonded to an atomic or molecular ligand, L. For example, M could be, but would not be restricted to, Al, W, Ta, Si, Zn, etc. The metal precursor reacts with the substrate when the substrate surface is prepared to react directly with the molecular precursor. For example, the substrate surface typically is prepared to include hydrogen-containing ligands, AH or the like, that are reactive with the metal precursor. Sulfur (S), oxygen (O), and Nitrogen (N) are some typical A species. The gaseous metal precursor molecule effectively reacts with all of the ligands on the substrate surface, resulting in deposition of a single atomic layer of the metal:

substrate-AH+MLₓ→substrate-AMLₓ₋₁+HL (1)

where HL is a reaction by-product. During the reaction, the initial surface ligands, AH, are consumed, and the surface becomes covered with L ligands, which cannot further react with metal precursor MLₓ. Therefore, the reaction self-terminates when all of the initial AH ligands on the surface are replaced with AMLₓ₋₁ species. The reaction stage is typically followed by an inert-gas purge stage that eliminates the excess metal precursor from the chamber prior to the separate introduction of a second reactive gaseous precursor material.

The second molecular precursor is then used to restore the surface reactivity of the substrate towards the metal precursor. This is done, for example, by removing the L ligands and redepositing AH ligands. In this case, the second precursor typically comprises the desired (usually nonmetallic) element A (i.e., O, N, S), and hydrogen (i.e., H₂O, NH₃, H₂S). The next reaction is as follows:

substrate-A-ML+AH_{y}→substrate-A-M-AH+HL (2)

This converts the surface back to its AH-covered state. (Here, for the sake of simplicity, the chemical reactions are not balanced.) The desired additional element, A, is incorporated into the film and the undesired ligands, L, are eliminated as volatile by-products. Once again, the reaction consumes the reactive sites (this time, the L terminated sites) and self-terminates when the reactive sites on the substrate are entirely depleted. The second molecular precursor then is removed from the deposition chamber by flowing inert purge-gas in a second purge stage.

In summary, then, the basic ALD process requires alternating, in sequence, the flux of chemicals to the substrate. The representative ALD process, as discussed above, is a cycle having four different operational stages:
1. MLₓ reaction;
2. MLₓ purge;
3. AH_{y} reaction; and
4. AH_{y} purge, and then back to stage 1.
   This repeated sequence of alternating surface reactions and precursor-removal that restores the substrate surface to its initial reactive state, with intervening purge operations, is a typical ALD deposition cycle. A key feature of ALD operation is the restoration of the substrate to its initial surface chemistry condition. Using this repeated set of steps, a film can be layered onto the substrate in equal metered layers that are all alike in chemical kinetics, deposition per cycle, composition, and thickness.

ALD has been used for making reflective interference filters. See for example the article “Introducing atomic layer epitaxy for the deposition of optical thin films” by D. Riihelä et al. (Thin Solid Films, Vol. 289, pp. 250-255, 1996). In this case, each layer is pure but since each layer is only about one molecular layer thick an average refractive index of a subset of layers can be made to be between two extremes by alternating high and low index layers. This approach requires a vacuum system, is relatively slow due to flushing the chamber after each pulse (each pulse depositing <1 nm), and does not yield intermediate refractive index layers, only when averaged over multiple layers. When multiple precursors are mixed and introduced there is competition for service sites and depletion of the more reactive material as the gases move farther from their introduction orifice into the chamber. The net result is a spatially varying material. If the precursors have separate orifices this only exacerbates the non-uniformity.

Spatial ALD is similar to ALD in that there are two or more reactive precursors, but the difference is that the gases are not pulsed but instead free flowing and a portion of the sample is moved from one effective chamber to another. In the simplest Spatial ALD configuration, the substrate is flat and forms a wall of a micro chamber. Each reactive gas is separated from the others by an inert gas. To apply layers, the sample is moved from one reactive chamber to the next. Usually this is accomplished by moving the sample in an oscillatory fashion. In some cases, if there are enough alternating orifices of reactive and inert gases the sample can make a single pass. This would be especially beneficial to web based deposition of very thin films.

There is a need therefore for a process which does not require the flushing of gases, the concomitant waste of materials and a much more rapid deposition of intermediate refractive index layers.

### SUMMARY OF THE INVENTION

The present invention represents a process of making a thin-film optical device including:

providing a substrate;

providing a plurality of gaseous material sources including a first gaseous source providing a first reactive gaseous material, a second gaseous source providing a second reactive gaseous material, a third gaseous source providing a third reactive gaseous material, and an inert gaseous material source providing an inert gaseous material, wherein the first reactive gaseous material and the second reactive gaseous material each react with the third reactive gaseous material but do not react with each other under a specified set of operating conditions;

providing a mixing system to mix a controllable ratio of the first and second reactive gaseous materials to provide a homogeneous gaseous mixture;

providing a delivery head in fluid communication with the mixing system, the third gaseous material source and the inert gaseous material source through a plurality of inlet ports, the mixing system being connected to a first inlet port, the third gaseous material source being connected to a second inlet port, and the inert gaseous material source being connected to a third inlet port, the delivery head including an output face having a first plurality of elongated substantially parallel output channels connected in fluid communication with the first inlet port, a second plurality of elongated substantially parallel output channels connected to a second inlet port, and a third plurality of elongated substantially parallel output channels connected to a third inlet port, wherein at least some of the third elongated output channels are positioned to separate at the first elongated output channels and the second elongated output channels;

simultaneously directing the homogeneous gaseous mixture, the third reactive gaseous material, and the inert gaseous material to flow through the first elongated output channels, the second elongated output channels, and the third elongated output channels, respectively, of the delivery head toward the substrate;

causing an oscillating relative motion between the delivery head and the substrate to cause the third reactive gaseous material to react with a portion of the substrate that has been treated with the homogeneous gaseous mixture thereby forming thin film layers of deposited material; and

controlling the mixing system to change the ratio of the first and second reactive gaseous materials as a function of time such that the thin film layers of deposited material have a varying composition.

This invention has the advantage that it enables the formation of an gradient index optical interference filter without the use a vacuum chamber.

It has the additional advantage that a gradient index is rapidly generated with molecular layer precision.

### BRIEF DESCRIPTION OF THE DRAWINGS

FIG. 1 is a cross-sectional side view of one embodiment of a delivery device for atomic layer deposition according to the present invention;

FIG. 2 is a cross-sectional side view of one embodiment of a delivery device for atomic layer deposition with a more detailed view of the distributions of the gases for the present invention;

FIG. 3 is a high-level diagram showing the components of a system for deposition of a gradient index optical filter according to an embodiment of the present invention;

FIG. 4 is a graph showing a refractive index profile specifying the refractive index versus height above the substrate for a two-band reflector;

FIG. 5 is a graph showing the calculated reflection spectrum of a thin film interference filter generated from the refractive index profile of FIG. 4;

FIG. 6 is a graph showing measured refractive index as a function of the percentage of the first reactive precursor in the homogeneous gaseous mixture;

FIG. 7 is a graph showing measured growth per oscillation as a function of the percentage of the first reactive precursor in the homogeneous gaseous mixture;

FIG. 8 is a graph showing the experimental reflection spectrum of a thin film interference filter generated according to the refractive index profile of FIG. 4; and

FIG. 9 is a graph showing the experimental reflection spectrum of a thin film interference filter generated based on the refractive index profile of FIG. 4 where the heights above the substrate are stretched by 15%.

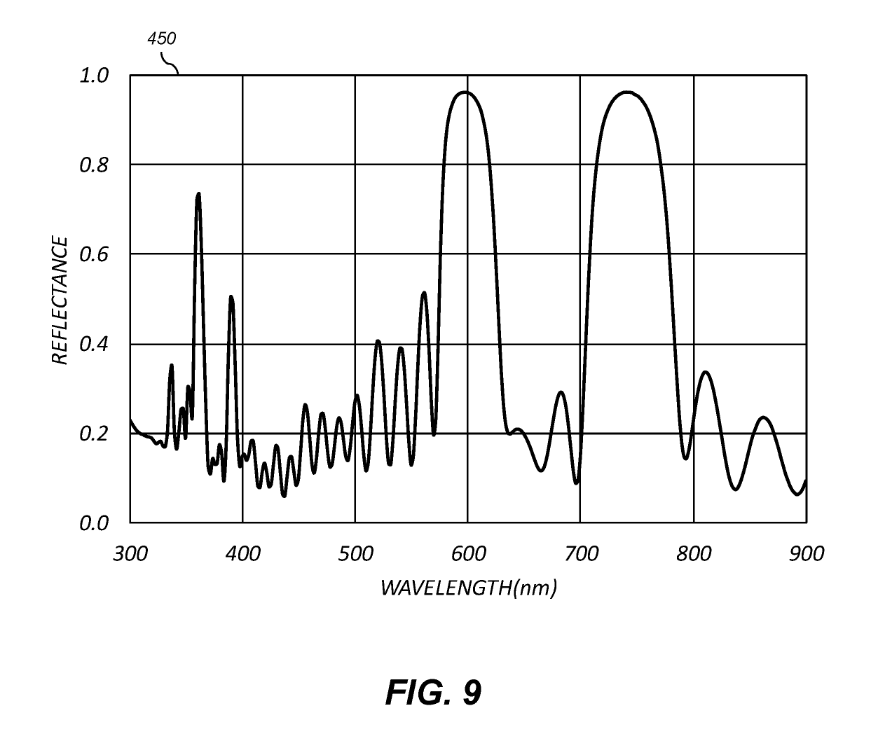

It is to be understood that the attached drawings are for purposes of illustrating the concepts of the invention and may not be to scale. Identical reference numerals have been used, where possible, to designate identical features that are common to the figures.

### DETAILED DESCRIPTION OF THE INVENTION

The invention is inclusive of combinations of the embodiments described herein. References to “a particular embodiment” and the like refer to features that are present in at least one embodiment of the invention. Separate references to “an embodiment” or “particular embodiments” or the like do not necessarily refer to the same embodiment or embodiments; however, such embodiments are not mutually exclusive, unless so indicated or as are readily apparent to one of skill in the art. The use of singular or plural in referring to the “method” or “methods” and the like is not limiting. It should be noted that, unless otherwise explicitly noted or required by context, the word “or” is used in this disclosure in a non-exclusive sense.

For the description that follows, the term “gas” or “gaseous material” is used in a broad sense to encompass any of a range of vaporized or gaseous elements, compounds, or materials. Other terms used herein, such as: reactant, precursor, vacuum, and inert gas, for example, all have their conventional meanings as would be well understood by those skilled in the materials deposition art. The figures provided are not drawn to scale but are intended to show overall function and the structural arrangement of some embodiments of the present invention.

For the description that follows, superposition has its conventional meaning, wherein elements are laid atop or against one another in such manner that parts of one element align with corresponding parts of another and that their perimeters generally coincide. The terms “upstream” and “downstream” have their conventional meanings as relates to the direction of gas flow.

As employed herein the term “optical coating” is intended to encompass rugate coatings that are used with radiation within the visible spectrum of wavelengths, and also coatings that are used with radiation within other wavelength bands, such as the ultraviolet (UV) and infrared (IR) spectrums.

There are two types of spatial ALD heads. In one the gasses flow down the open channel or slot perpendicular to the transport direction. This type is exemplified in U.S. Pat. No. 7,456,429, which is incorporated herein by reference. This type will suffer from the same issues that standard ALD does in that the when two gases are mixed, the more reactive one will deposit at the entrance and the ratio will change as the gas flow moves to the exhaust.

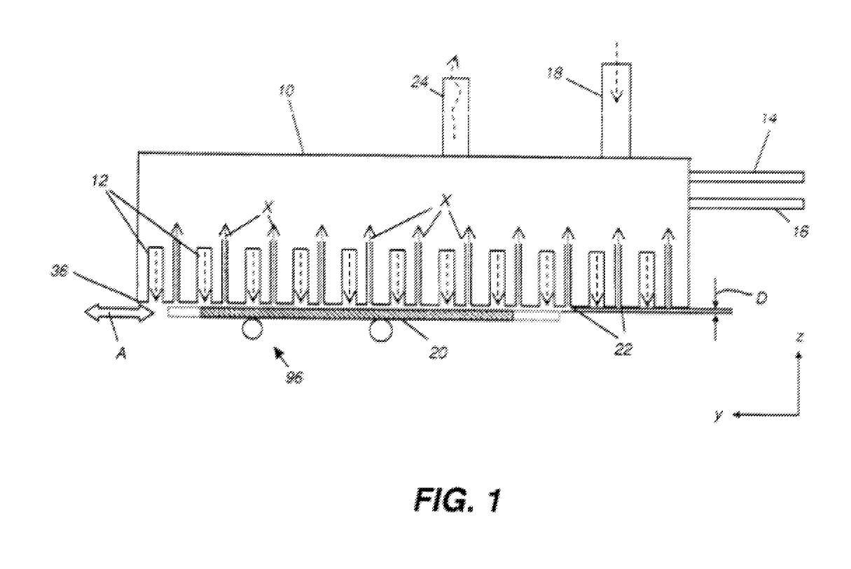

The second type of deposition head is exemplified in U.S. Pat. Nos. 7,572,686 and 8,182,608, which are incorporated herein by reference. This deposition head is the type shown in FIG. 1 wherein the gases impinge on the sample substantially perpendicularly and flow substantially parallel to the transport direction. This type of deposition head is preferred for use in the method of the present invention.

Referring to FIG. 1, there is shown a cross-sectional side view of an exemplary embodiment of a delivery head 10 for atomic layer deposition onto a substrate 20 in accordance with the present invention. Delivery head 10 has a gas inlet conduit 14 that serves as an inlet port for accepting a first gaseous material, a gas inlet conduit 16 for an inlet port that accepts a second gaseous material, and a gas inlet conduit 18 for an inlet port that accepts a third gaseous material. These gases are emitted at a depositing output face 36 via output channels 12, having a structural arrangement that may include a diffuser.

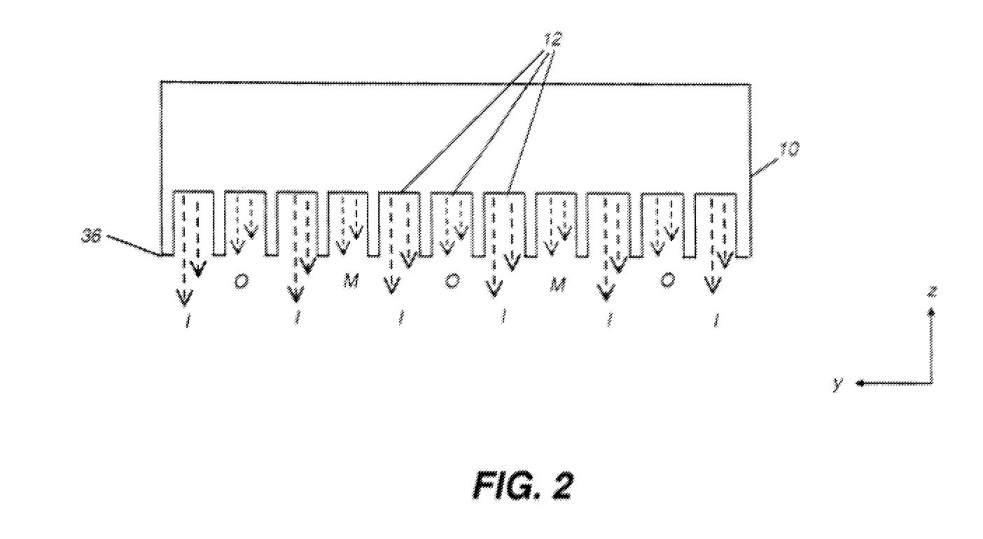

The dashed line arrows in FIG. 1 and subsequent FIG. 2 refer to the delivery of gases to substrate 20 from delivery head 10. In FIG. 1, dotted line arrows also indicate paths for gas exhaust (shown directed upwards in this figure) through exhaust channels 22, in communication with an exhaust conduit 24 that provides an exhaust port. (For simplicity of description, gas exhaust is not indicated in FIG. 2.) Because the exhaust gases may still contain quantities of unreacted precursors, it may be undesirable to allow an exhaust flow predominantly containing one reactive species to mix with one predominantly containing another species. As such, it is recognized that the delivery head 10 may contain several independent exhaust conduits 24. The pressure generated by the flow of the gases through the output channels 12 create a gas fluid bearing that maintains a substantially uniform distance between the output face 36 of the delivery head 10 and the substrate 20.

In an exemplary embodiment, gas inlet conduits 14 and 16 are adapted to accept first and second gases that react sequentially on the substrate surface to effect ALD deposition, and gas inlet conduit 18 receives a purge gas that is inert with respect to the first and second gases. Delivery head 10 is spaced a distance D from substrate 20, which may be provided on a substrate support 96, as described in more detail subsequently.

Reciprocating motion can be provided between the substrate 20 and the delivery head 10, either by movement of the substrate 20, by movement of the delivery head 10, or by movement of both the substrate 20 and the delivery head 10. In the exemplary embodiment shown in FIG. 1, substrate 20 is moved by a substrate support 96 across the output face 36 in a reciprocating fashion, as indicated by the arrow A and by phantom outlines to the right and left of substrate 20 in FIG. 1. It should be noted that reciprocating motion is not always required for thin-film deposition using delivery head 10. Other types of relative motion between substrate 20 and delivery head 10 could also be provided, such as movement of either substrate 20 or delivery head 10 in one or more directions.

The cross-sectional view of FIG. 2 shows gas flows emitted over a portion of the output face 36 of delivery head 10 (with the exhaust path omitted as noted earlier). In this particular arrangement, each output channel 12 is in gaseous flow communication with one of gas inlet conduits 14, 16 or 18 seen in FIG. 1. Each output channel 12 delivers typically a first reactive gaseous material M, or a second reactive gaseous material O, or a third inert gaseous material I.

The configuration of FIG. 2 shows a relatively basic or simple arrangement of gases. It is envisioned that a plurality of non-metal deposition precursors (like material O) or a plurality of metal-containing precursor materials (like material M) may be delivered sequentially at various ports in a single thin-film deposition. Alternately, a mixture of reactive gases, for example, a mixture of metal precursor materials or a mixture of metal and non-metal precursors may be applied at a single output channel when making complex thin film materials, for example, having alternate layers of metals or having lesser amounts of dopants admixed in a metal oxide material. Significantly, an inter-stream labeled I for an inert gas, also termed a purge gas, separates any reactive gas channels in which the gases are likely to react with each other. First and second reactive gaseous materials M and O react with each other to effect ALD deposition, but neither reactive gaseous material M nor O reacts with the inert gaseous material I.

The nomenclature used in FIG. 2 and following suggests some typical types of reactive gases. For example, first reactive gaseous material M can be a metal-containing compound, such as a material containing zinc; and second reactive gaseous material O can be an oxygen or chalcogenide containing gaseous material. The inert gaseous material I can be nitrogen, argon, helium, or other gases commonly used as purge gases in ALD systems. Inert gaseous material I is inert with respect to first and second reactive gaseous materials M and O. Reaction between the first and second reactive gaseous materials would form a metal oxide or other binary compound, such as zinc oxide ZnO or ZnS, used in semiconductors, in one embodiment.

The delivery head 10 may have one or more sets of reactive precursors. A set of reactive precursors includes both M and O reactants, along with the concomitant inert gas slots and exhaust slots. If there are more than one set, then more layers are deposited per pass of the substrate 20 under the delivery head 10.

In this invention, two or more precursor gas streams are combined before exhausting from a single output channel 12 in the delivery head 10. This is preferably obtained by joining the gas flows external to the delivery head 10 but may occur in the delivery head 10 if the gases are sufficiently mixed before impingement on the surface of the substrate 20. Two precursors are required (e.g., reactants M₁ and M₂) which do not chemically interact, at least at the temperature of the delivery head 10. Both precursors will react with third precursor (e.g., reactant O). The reactions yield M₁O and M₂O respectively. When the M₁ and M₂ precursors are mixed and react with the surface of O, a mix of M₁O and M₂O results. In a preferred configuration, the M₁O and M₂O precursors are chosen such that the respective refractive indexes of the films are maximally different.

Preferred examples of M₁O and M₂O are TiO₂ and Al₂O₃ which can be generated as films by spatial ALD having refractive indexes of 2.4 and 1.6, respectively. Any high refractive index materials may be used when coupled with a low refractive material as long as the precursors have the attributes mentioned and are not significantly absorbing at the desired wavelengths. Other example high refractive index materials are ZnO, ZrO₂, HfO₂. A low refractive index material is SiO₂.

Two metal precursors which do not react until higher than 200° C. are trimethyl aluminum and titanium tetrachloride. When used with water as the co-reactant, it is possible to deposit a film of any refractive index between 1.6 and 2.4.

For visible wavelength filters, exemplary materials for substrate 20 are BK-7, fused silica, and sapphire. For IR wavelength filters, exemplary materials for substrate 20 are sapphire, zinc selenide, and germanium.

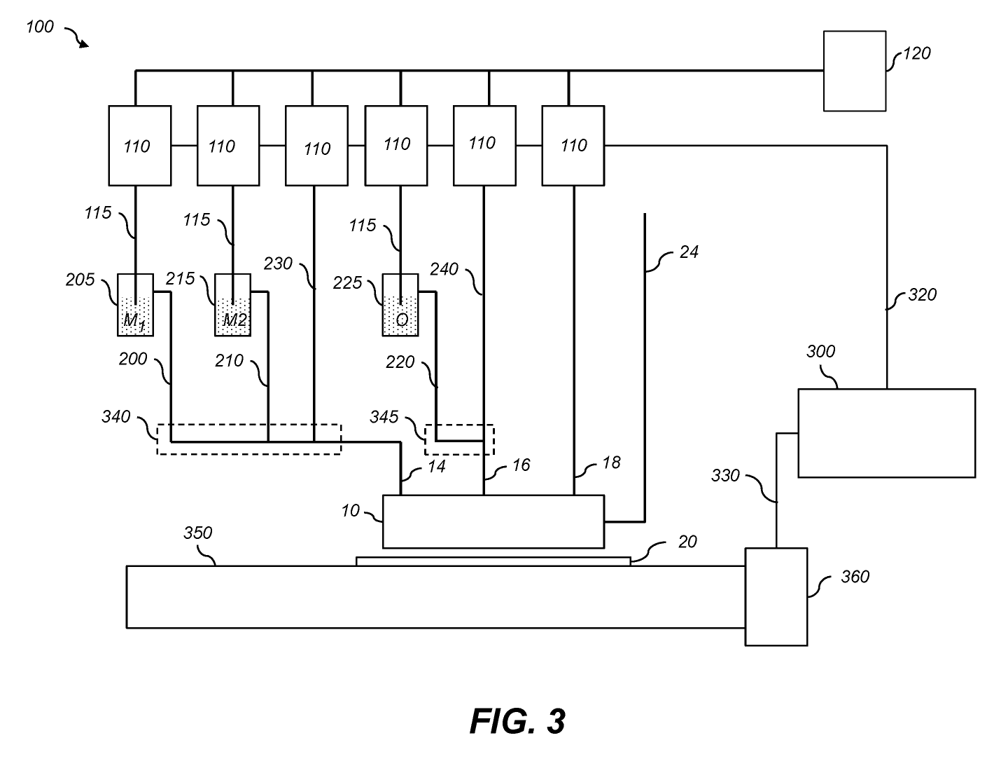

A diagram illustrating a deposition system 100 is shown in FIG. 3. A controller 300 (which can also be referred to as a computer) controls the gas flows through delivery head 10 to form a thin-film optical device on substrate 20, such that the layers of deposited material have a varying composition. The controller has access to information necessary to control the gas flows in order to achieve a layer of deposited material having a specified refractive index for each oscillation of the substrate 20 over the delivery head 10 in order to form a thin film coating having a specified refractive index as a function of height. This information is generated from data characterizing the refractive index and the growth rate of the deposited thin film as a function of the ratio of the M₁ and M₂ precursors. The information for the gas flows is transmitted along wiring 320 to control mass flow controllers 110 in sync with the motion of the substrate 20.

The controller 300 also controls the motion of the substrate 20 by communicating signals to a motor 360 (or to a motor controller) through wiring 330. Typically, the substrate 20 is oscillated back and forth on a stage 350 with an acceleration at each reversal of direction and an intervening interval of constant velocity. Movement of the substrate 20 in a forward direction and then back in a reverse direction is considered to be an “oscillation,” or equivalently a “cycle.”

The delivery head 10 and stage 350 are preferably heated by a thermal heater, radiant heater, or any other method known to those skilled in the art. The stage 350 in FIG. 3 is shown moving the substrate 20 below the deposition head but it could be in any orientation (e.g., in an inverted orientation or a vertical orientation).

Bubblers 205 and 215 are fed by separate inert gas conduits 115 controlled by corresponding mass flow controllers 110 which receive an inert gas flow from an inert gas source 120. The bubblers 205 and 215 contain first and second reactive precursors (e.g., metal precursors M₁ and M₂), respectively. The output of the bubbler 205 is a gas flow including the first reactive gaseous material (e.g., the metal precursor M₁) flowing through a first reactive gas conduit 200. Likewise, the output of the bubbler 215 is a gas flow including the second reactive gaseous material (e.g., the metal precursor M₂) flowing through a second reactive gas conduit 210. The bubbler 205, together with the first reactive gas conduit 200, the inert gas source 120, and the corresponding mass flow controller 110 and inert gas conduit 115 can be considered to be a first gaseous source which provides a gas flow of the first reactive gaseous material. Likewise, the bubbler 215, together with the first reactive gas conduit 210, the inert gas source 120, and the corresponding mass flow controller 110 and inert gas conduit 115 can be considered to be a second gaseous source which provides a gas flow of the second reactive gaseous material

The gas flows of the first and second reactive gaseous materials are combined in a mixing system 340, together with an inert gas flow in an inert gas conduit 230, to provide a homogeneous gaseous mixture to gas inlet conduit 14. In an exemplary embodiment, the mixing system 340 is simply a series of conduit joints where the gas flows through the individual conduits are merged into a combined gas flow. With this arrangement, the gaseous elements in the individual gas flows will mix together to provide a homogeneous gaseous mixture. Other types of mixing systems 340 can also be used including those which include active or passive mixing devices which can be used to speed the formation of the homogeneous mixture. An example of an active mixing device would be a stirring device which stirs the gas flow as it passes through the mixing system 340. An example of a passive mixing device would be a series of baffles which the gas flow passes through to redirect the gas flow. The controller 300 controls the concentrations and the ratio of the first and second reactive gaseous materials in the homogeneous gaseous mixture, together with the total gas flow through the gas inlet conduit 14, by controlling the corresponding mass flow controllers 110.

Similarly, bubbler 225 is fed by an inert gas conduits 115 controlled by a corresponding mass flow controllers 110 which receives an inert gas flow from the inert gas source 120. The bubbler 225 contains a third reactive precursors (e.g., reactant O). The output of the bubbler 225 is a gas flow including the third reactive gaseous material (e.g., the reactant O) flowing through a third reactive gas conduit 220. This gas flow is combined with an inert gas flow in an inert gas conduit 240 using a mixing system 345 to provide a gas flow including the third reactive gaseous material through gas inlet conduit 16. The controller 300 controls the concentration of the third reactive gaseous, together with the total gas flow provided through the gas inlet conduit 16, by controlling the corresponding mass flow controllers 110. The bubbler 225, together with the third reactive gas conduit 220, the inert gas source 120, and the corresponding mass flow controller 110 and inert gas conduit 115 can be considered to be a third gaseous source which provides a gas flow of the third reactive gaseous material.

The homogeneous gaseous mixture including the first and second reactive gaseous materials (e.g., reactants M₁ and M₂) flowing through the gas inlet conduit 14, and the third reactive gaseous material (e.g., reactant O) flowing through the gas inlet conduit 16 enter the delivery head 10, together with an inert purge gas flowing through gas inlet conduit 18. A gas manifold in the delivery head 10 is used to direct the gas flows to the appropriate output channels 12 (FIG. 1) in order to provide the desired ALD process onto the substrate 20 as it is moved past the output channels 12. Exhaust gases from exhaust channels 22 (FIG. 1) are exhausted from the delivery head 10 through one or more exhaust conduits 24, which are generally connected to corresponding vacuum systems.

It may be appreciated that the bubblers 205, 215, 225 are only used for cases where the reactive precursors are liquids. In other embodiments, one or more of the reactive precursors can be gaseous materials. In this case, the reactive gaseous materials can be supplied by a corresponding gas source and controlled directly with an associated mass flow controller.

To generate the gradient index filter, it is necessary to know both the refractive index and the growth rate for different ratios of the first and second reactive gaseous materials in the homogeneous gaseous mixture. Usually this can be obtained by direct measurements of uniform thick films. With that information, the appropriate gas flows needed to provide the appropriate ratios for each oscillation of the substrate 20 can be calculated. A table of the required gas flows can be predetermined, or the information can be generated on the fly. This information can then be used to control the mass flow controllers 110 in sync with the oscillations. The syncing can be closed loop where after each oscillation a signal is sent to the controller 300 to transmit the information to the mass flow controllers 110. The syncing can also be open loop where the length of time for each oscillation is known and the information is transmitted to the mass flow controllers 110 at the appropriate time.

### EXAMPLE #1

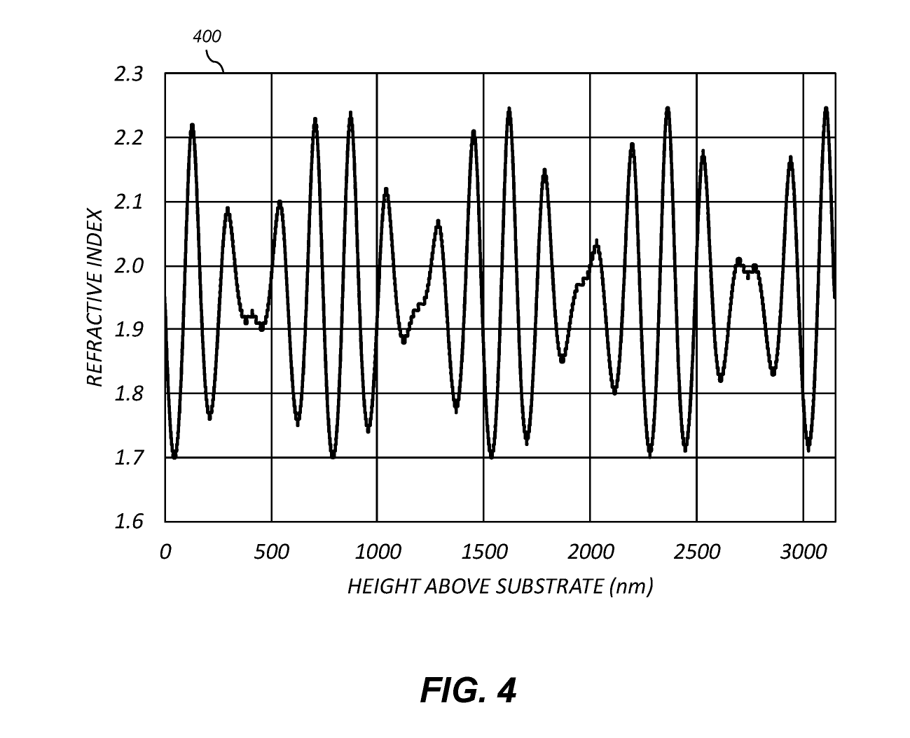

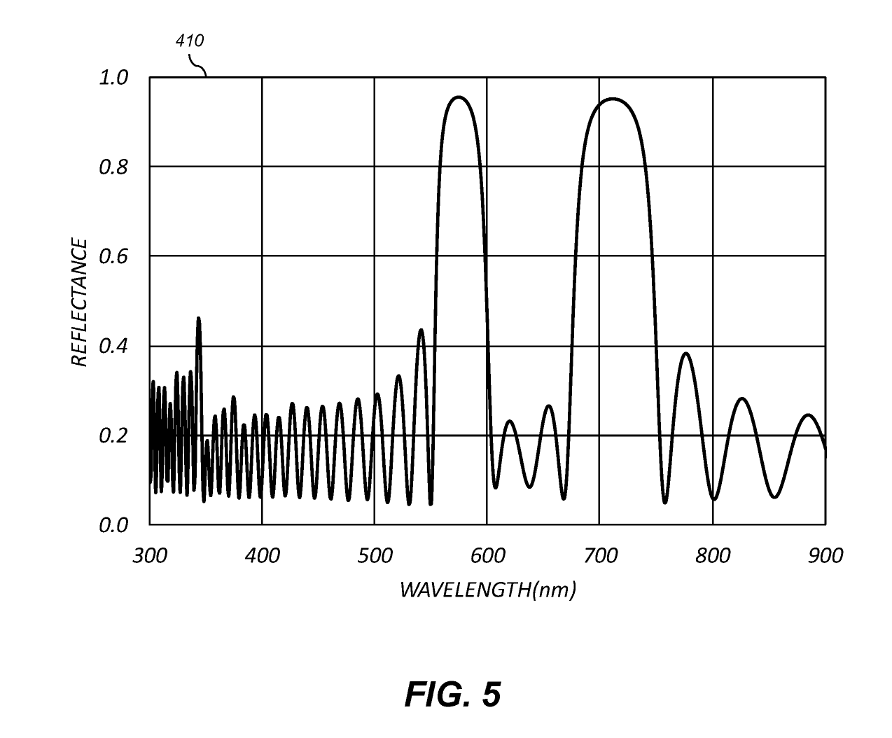

The open source program Openfilters was used to generate a target refractive index versus height above substrate profile for a two-band reflection filter having bands centered on 580 nm and 710 nm. FIG. 4 is a graph 400 showing the resulting target refractive index versus height from substrate, and FIG. 5 is a graph 410 showing the corresponding calculated reflection spectrum. This reflection filter is an example of an optical interference filter or rugate filter.

A filter design was determined where the first reactive precursor M₁ was titanium tetrachloride (TiCl₄) and the second reactive precursor M₂ was trimethyl aluminum (TMA). The flow rates of the first and second reactive gases were controlled by mass flow controllers 110 passing dry nitrogen through bubblers 205, 215 containing the reactive precursors. The total gas flow of nitrogen passing through the bubblers 205, 215 always totaled 25 sccm. They were mixed with a 1500 sccm dilution of dry nitrogen through inert gas conduit 230 and provided to the metal output channels 12 (FIG. 1) on the delivery head 10. Water was used as the oxygen source using 40 sccm through bubbler 225 and was mixed with a 2250 sccm dilution of dry nitrogen through inert gas conduit 240 and provided to the oxygen output channels 12. The metal and oxygen output channels 12 were separated by purge gas output channels 12 supplied by dry nitrogen at 3000 sccm.

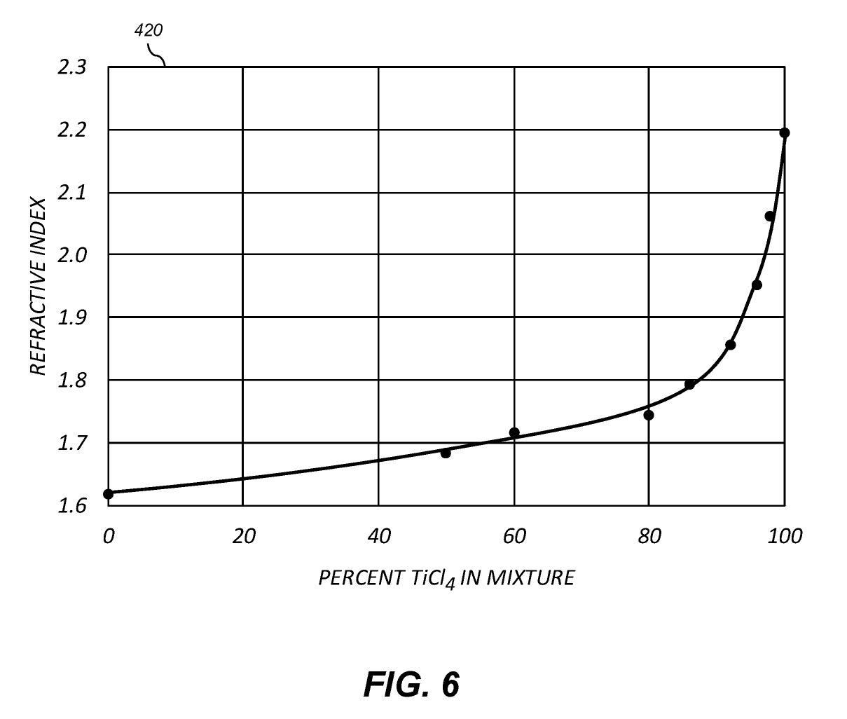

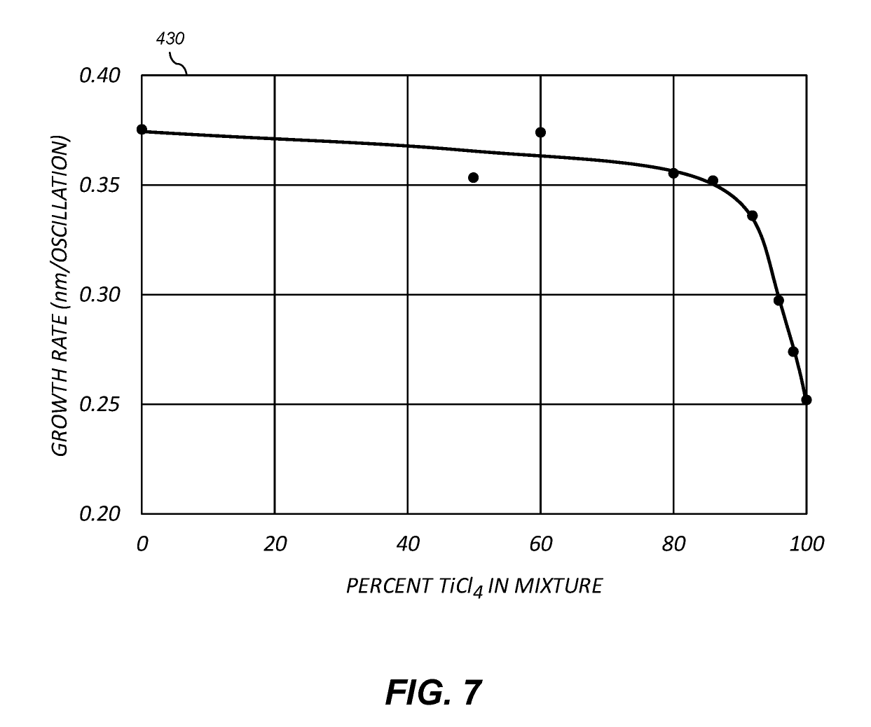

The refractive index as a function of the percentage of TiCL₄ in the homogeneous gaseous mixture was determined experimentally using the deposition system 100 (FIG. 3) to deposit thin films on a BK-7 glass substrate 20. The resulting first calibration function is shown in graph 420 of FIG. 6. The growth per oscillation as a function of the percentage of TiCL₄ in the homogeneous gaseous mixture was also determined and the resulting second calibration function is shown in graph 430 of FIG. 7. The delivery head 10 was a double outlet head giving four deposition layers per oscillation. The refractive index profile of FIG. 4 was used in conjunction with the calibration functions of FIGS. 6-7 to determine a table of gas flows versus oscillation number required to form an interference filter having the reflection spectrum shown in FIG. 4.

A BK-7 glass substrate 20 was placed under the delivery head 10. The controller 300 was loaded with the data for the flow rates versus oscillation number. A total of 10,436 oscillations were used where four layers were deposited per oscillation. The acceleration/deceleration was set to 1920 mm/sec² and the substrate velocity was 101.6 mm/sec. The total distance traveled by the substrate 20 was 36 mm. This gives an oscillation time of 0.74 sec. The gas flow rates were therefore adjusted every 0.74 sec.

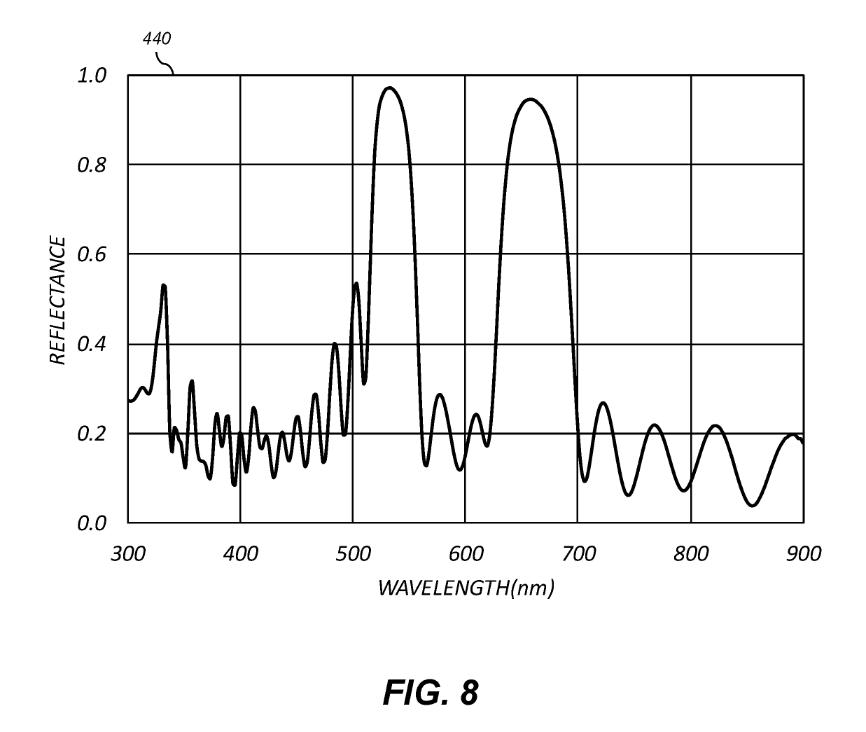

The delivery head 10 and the substrate 20 were heated to 180° C. and the program was run, finishing in 129 minutes. The resulting reflection spectrum measured at 6 degrees off axis is shown in the graph 440 of FIG. 8. Note that two reflection bands were obtained as expected. It can be seen that the peak wavelengths of the reflection bands are slightly blue shifted relative to the theoretical reflection spectrum shown in FIG. 5, presumably due to small calibration errors of the growth per oscillation.

### EXAMPLE #2

To demonstrate that the reflection bands can easily be shifted, and that errors in the laydown calibrations were likely responsible for the shifts observed in FIG. 6, the x-axis of target refractive index profile in FIG. 4 was stretched by 15% and a new table of gas flows versus oscillation number was determined. The total number of oscillation now became 12,001 and required 149 minutes to complete. The measured reflection spectrum of the resulting thin film filter is shown in the graph 450 of FIG. 8. It can be observed that the peak wavelengths of the reflection bands have both been shifted in the red direction as expected.

It is clear that other refractive index profiles can be obtained by this method in a relatively short period of time compared to conventional ALD and with better layer thickness and composition control than are obtainable using sputtering processes. While only two examples are given it will be obvious to one skilled in the art how to achieve optical interference filters with other reflection or transmission spectra shapes. Furthermore, while the exemplary embodiments described here have related to the formation of optical interference filters (e.g., rugate filters), it will be obvious to one skilled in the art that the same fabrication processes can be used to form other types of thin-film optical devices. The invention is particularly well-suited to thin-film optical devices which require depositing layers having different compositions to provide different indices of refraction (e.g., a gradient index profile). Other examples of thin-film optical devices that can be fabricated using the process of the present invention would include waveguides that are useful for guiding light on the surface of a substrate.

The invention has been described in detail with particular reference to certain preferred embodiments thereof, but it will be understood that variations and modifications can be effected within the spirit and scope of the invention.

### PARTS LIST

10 delivery head
12 output channel
14 gas inlet conduit
16 gas inlet conduit
18 gas inlet conduit
20 substrate
22 exhaust channel
24 exhaust conduit
36 output face
96 substrate support
100 deposition system
110 mass flow controller
115 inert gas conduit
120 inert gas source
200 first reactive gas conduit
205 bubbler
210 second reactive gas conduit
215 bubbler
220 third reactive gas conduit
225 bubbler
230 inert gas conduit
240 inert gas conduit
300 controller
320 wiring
330 wiring
340 mixing system
345 mixing system
350 stage
360 motor
400 graph
410 graph
420 graph
430 graph
440 graph
450 graph

1. A process of making a thin-film optical device comprising:
providing a substrate;
providing a plurality of gaseous material sources including a first gaseous source providing a first reactive gaseous material, a second gaseous source providing a second reactive gaseous material, a third gaseous source providing a third reactive gaseous material, and an inert gaseous material source providing an inert gaseous material, wherein the first reactive gaseous material and the second reactive gaseous material each react with the third reactive gaseous material but do not react with each other under a specified set of operating conditions;
providing a mixing system to mix a controllable ratio of the first and second reactive gaseous materials to provide a homogeneous gaseous mixture;
providing a delivery head in fluid communication with the mixing system, the third gaseous material source and the inert gaseous material source through a plurality of inlet ports, the mixing system being connected to a first inlet port, the third gaseous material source being connected to a second inlet port, and the inert gaseous material source being connected to a third inlet port, the delivery head including an output face having a first plurality of elongated substantially parallel output channels connected in fluid communication with the first inlet port, a second plurality of elongated substantially parallel output channels connected to a second inlet port, and a third plurality of elongated substantially parallel output channels connected to a third inlet port, wherein at least some of the third elongated output channels are positioned to separate at the first elongated output channels and the second elongated output channels;
simultaneously directing the homogeneous gaseous mixture, the third reactive gaseous material, and the inert gaseous material to flow through the first elongated output channels, the second elongated output channels, and the third elongated output channels, respectively, of the delivery head toward the substrate;
causing an oscillating relative motion between the delivery head and the substrate to cause the third reactive gaseous material to react with a portion of the substrate that has been treated with the homogeneous gaseous mixture thereby forming thin film layers of deposited material; and
controlling the mixing system to change the ratio of the first and second reactive gaseous materials as a function of time such that the thin film layers of deposited material have a varying composition.

2. The process of claim 1, wherein the thin film layers of deposited material have a varying refractive index.

3. The process of claim 1, further including:
receiving a refractive index profile specifying the refractive index as a function of height above the substrate;
receiving a first calibration function relating the refractive index of the deposited thin film layer as a function of the ratio of the first and second reactive gaseous materials;
receiving a second calibration function relating a growth rate of the deposited material as a function of the ratio of the first and second reactive gaseous materials; and
controlling the ratio of the first and second reactive gaseous materials as a function of time responsive to the refractive index profile and the first and second calibration functions.

4. The process of claim 3, wherein the thin-film optical device is an optical interference filter, and wherein the refractive index profile is determined to provide a specified reflectance spectrum or transmission spectrum for the optical interference filter.

5. The process of claim 3, wherein the thin-film optical device is an optical waveguide.

6. The process of claim 1, wherein a pressure generated by the flow of the one or more of the homogeneous gaseous mixture, the third reactive gaseous material, and the inert gaseous material create a gas fluid bearing that maintains a substantially uniform distance between the output face of the delivery head and the substrate.

7. The process of claim 1, wherein the first and second reactive gaseous materials are metal-containing precursor materials.

8. The process of claim 1, wherein the third reactive gaseous materials is a non-metal precursor material.

9. The process of claim 1, wherein the first reactive gaseous material and the third reactive gaseous material react to form a high refractive index material and the second reactive gaseous material and the third reactive gaseous material react to form a low refractive index material, wherein the high refractive index material has a higher refractive index than the low refractive index material.

10. The process of claim 9, wherein the high refractive index material is TiO₂, ZnO, ZrO₂ or HfO₂.

11. The process of claim 9, wherein the low refractive index material is Al₂O₃ or SiO₂.

12. The process of claim 1, wherein the mixing system mixes the first and second reactive gaseous materials by merging a gas flow of the first reactive gaseous material in a first conduit and a gas flow of the second reactive gaseous material in a second conduit to form a combined gas flow in a third conduit.

13. The process of claim 1, wherein the mixing system also mixes a controllable gas flow of the inert gaseous material into the homogeneous gaseous mixture.
